(19) United States
(12) Patent Application Publication
(10) Pub. No.: US 2025/0102633 A1
(43) Pub. Date: Mar. 27, 2025

(54) OPTICAL PACKAGING STRUCTURE FOR LIDAR

(71) Applicant: Lumentum Operations LLC, San Jose, CA (US)

(72) Inventors: Chong Yang QIN, Dongguan City (CN); Xianwen Feng, Dongguan City (CN); Vincent Wei Hong, Hong Kong (HK); Vivian Wei Ma, Hong Kong (HK); Ying Wai Sun, Hong Kong (HK)

(21) Appl. No.: 18/798,174

(22) Filed: Aug. 8, 2024

(30) Foreign Application Priority Data
Sep. 23, 2023 (CN) 202311234039.5

(51) Int. Cl. G01S 7/481; H05K 1/11; H05K 5/00; H05K 5/02; H05K 7/20

(52) U.S. Cl. CPC G01S 7/4813; H05K 1/11; H05K 5/0069; H05K 5/0209; H05K 7/2039; H05K 2201/10734

(57) ABSTRACT

The present invention relates to the field of LIDAR technology, and in particular to an optical package structure for a LIDAR. An optical package structure for a LIDAR includes a housing; a laser transceiver component arranged in the housing, and configured to emit a laser and to receive for detection; a temperature control component arranged in the housing and connected to the laser transceiver component; and a conduction circuit board arranged on the housing and electrically connected to an external circuit board. The conduction circuit board is arranged to be electrically connected to the laser transceiver component. The optical package structure for the LIDAR according to the present invention is in a separated package form, is compact in structure and facilitates improving the versatility of the product; and a peripheral control circuit part thereof suitable for different scenarios can be designed by a user according to his or her own demands, so that the production and design costs for the user are reduced.

### CROSS-REFERENCE TO RELATED APPLICATION

This Patent Application claims priority to Chinese Patent Application No. 202311234039.5, filed on Sep. 23, 2023, and entitled “OPTICAL PACKAGING STRUCTURE FOR LIDAR.” The disclosure of the prior Application is considered part of and is incorporated by reference into this Patent Application.

### FIELD

The present invention relates to the field of LIDAR technology, and in particular to an optical package structure for a LIDAR.

### BACKGROUND

LIDAR is a radar system which emits a laser beam to detect a feature quantity such as a position and velocity of a target. The LIDAR may obtain relevant parameters such as the distance and velocity of the target by emitting a laser beam (a single ray or multiple rays) to the target, then comparing a reflected signal with the emitted signal, and analyzing a Time of Flight (TOF) or a frequency difference (Doppler frequency shift) for the signals.

LIDAR is an important sensor in intelligent driving and intelligent robots. With the increasing development of intelligent driving and intelligent robot technology, the requirements for cost, volume and power consumption of LIDAR become higher and higher. A conventional LIDAR module generally includes structures such as an optical component, a control circuit, a semiconductor cooler and a heat sink. However, in different application scenarios, different LIDAR structures need to be adopted, so the structural needs of LIDAR are various. Especially, it is often necessary to redesign the control circuit part according to different application scenarios. However, the redesign and production will lead to disadvantages such as the increase of production cost, the extension of order cycle, poor versatility of products, and waste of resources.

The above-mentioned disadvantages are expected to be overcome by those skilled in the art.

### SUMMARY

An object of the present invention is to provide an optical package structure for a LIDAR with excellent versatility and compact structure to overcome the above-mentioned disadvantages of the prior art.

In order to solve the above technical problem, the present invention employs the following technical solutions.

An optical package structure for a LIDAR includes a housing; a laser transceiver component arranged in the housing, and configured to emit a laser and to receive for detection; a temperature control component arranged in the housing and connected to the laser transceiver component; and a conduction circuit board arranged on the housing and arranged to be electrically connected to an external circuit board. The conduction circuit board is arranged to be electrically connected to the laser transceiver component.

The present invention enables the integration of parts with lower iterative update frequencies in the LIDAR module into an independent optical package structure. The optical package structure can be electrically connected to the external circuit board via the conduction circuit board. The optical package structure has a compact structure and good versatility, a peripheral control circuit part thereof suitable for different scenarios can be designed by the user according to his or her own demands, and then the optical package structure is electrically connected with the peripheral control circuit part. Thereby, it can meet different users' demands, reduce the production and design costs for the user. Meanwhile, the temperature control component can control the temperature of the laser transceiver component, guarantee the normal operation of the optical package structure, improve the reliability of the optical package structure, and reduce the user's difficulty in the design and use.

Further, the housing includes a receiving housing arranged to carry the laser transceiver component and the temperature control component, an outer housing arranged to cover the receiving housing, and a lower cover plate arranged at a bottom of the receiving housing. A mounting hole is provided on the lower cover plate, and the conduction circuit board is arranged to be embedded in the mounting hole.

Preferably, a first accommodating cavity arranged for placing the temperature control component is provided on an upper surface of the receiving housing; and a second accommodating cavity arranged to correspond to the first accommodating cavity and to carry the laser transceiver component is provided on a lower surface of the receiving housing. The temperature control component includes a semiconductor cooler placed in the first accommodating cavity and a connector connected to the semiconductor cooler; a cold end of the semiconductor cooler is connected to the laser transceiver component; and a hot end of the semiconductor cooler is connected to the outer housing. The optical package structure is easy to assemble and compact in structure.

Preferably, the first accommodating cavity is arranged to be communicated with the second accommodating cavity, and the cold end of the semiconductor cooler is arranged to be directly contacted with and connected to the laser transceiver component. This facilitates improving the efficiency of semiconductor cooler upon regulating the temperature of laser transceiver component.

Preferably, the outer housing arranged to cover the receiving housing includes a first housing arranged on an upper surface of the receiving housing and a second housing arranged to outside surround the receiving housing, and a gap is existed between the first housing and the second housing. This can prevent the first housing connected with the hot end of the semiconductor cooler from transferring heat to the second housing, and then transferring heat to the receiving housing through the second housing, thereby affecting the heat-dissipating effect of the optical package structure.

Preferably, a plurality of positioning stubs is provided on the upper surface of the receiving housing; and a plurality of insertion holes arranged to correspond one-to-one with the positioning stubs and for an insertion of the positioning stubs are provided in the first housing. In this way, the first housing can be quickly assembled on the receiving housing by an operator, thereby simplifying the assembling process and improving the assembling efficiency.

Preferably, a thermal insulation layer arranged for thermally insulating the first housing from the second housing is provided in the gap between the first housing and the second housing. This further reduces the risk of heat at the first housing being transferred through the second housing to the receiving housing.

Preferably, the connector includes a flexible circuit board connected to the semiconductor cooler and extending to an outside of the housing, and a pin arranged at an end of the flexible circuit board away from the housing and electrically connected with the external circuit board.

Preferably, the connector includes a flexible circuit board having a U-shaped structure; the flexible circuit board includes a first horizontal segment connected to the semiconductor cooler, a second horizontal segment arranged in parallel with the first horizontal segment and electrically connected to the conduction circuit board, and a bent segment arranged to connect the first horizontal segment with the second horizontal segment and having a bent structure.

The flexible circuit board occupies a small space in the optical package structure, which facilitates the arrangement of other components; meanwhile, the flexible circuit board can be entirely received in the housing, so that the structure of the optical package structure is more compact, which facilitates reducing the volume of the optical package structure and enhancing its compatibility.

Further, a plurality of ball grid array solder balls are provided on a side of the conduction circuit board facing the outside. In this way, the electrical conduction with the external circuit board is achieved, and there are advantages such as a good heat-dissipating performance, firm pins and good electrical performance.

The advantageous effects of the present invention compared with the prior art are as follows:

1. According to an optical package structure for a LIDAR of the present invention, the laser transceiver component and the temperature control component are packaged in the housing, thereby realizing the integration of the parts with lower iterative update frequencies in the LIDAR module into an independent optical package structure; and the housing is provided with the conductive circuit board, and thus the optical package structure can be electrically connected to the external circuit board via the conduction circuit board. The optical package structure has a compact structure and good versatility, and a peripheral control circuit part thereof with a high change frequency and suitable for different scenarios can be designed by the user according to his or her own demands, and then the optical package structure is electrically connected with the peripheral control circuit part. Thereby, it can meet different users' demands, which facilitates reducing the production and design costs for the user.

2. Since the temperature control component and the optical component are packaged together, the temperature control component can control the temperature of the laser transceiver component, which can guarantee the normal operation of the optical package structure, improve the reliability of the optical package structure, and reduce the user's difficulty in the design and use.

3. The first horizontal segment and the second horizontal segment in the flexible circuit board are disposed parallel with each other, and the bent segment presents a bent structure and connects the first horizontal segment with the second horizontal segment; and the second horizontal segment is electrically connected to the conduction circuit board. In this way, the flexible circuit board can be entirely received in the housing, so that the structure of the optical package structure is made more compact, which facilitates reducing the volume of the optical package structure and enhancing its compatibility.

### BRIEF DESCRIPTION OF THE DRAWINGS

FIG. 1 is an overall structural schematic diagram of an optical package structure for a LIDAR according to a first embodiment of the present invention;

FIG. 2 is an overall structural schematic diagram of the optical package structure for the LIDAR according to the first embodiment of the present invention as viewed from another angle;

FIG. 3 is a perspective diagram of the optical package structure for the LIDAR according to the first embodiment of the present invention;

FIG. 4 is a cross-sectional view of the optical package structure for the LIDAR according to the first embodiment of the present invention;

FIG. 5 is a structural schematic diagram of a receiving housing in the optical package structure for the LIDAR according to the first embodiment of the present invention;

FIG. 6 is a structural schematic diagram of the receiving housing in the optical package structure for the LIDAR according to the first embodiment of the present invention as viewed from another angle;

FIG. 7 is a structural schematic diagram of a temperature control component in the optical package structure for the LIDAR according to the first embodiment of the present invention;

FIG. 8 is a structural schematic diagram of the temperature control component in an optical package structure for the LIDAR according to a second embodiment of the present invention; and

FIG. 9 is a structural schematic diagram of the temperature control component in the optical package structure for the LIDAR according to the second embodiment of the present invention.

### DESCRIPTION OF REFERENCE NUMERALS

1. Housing; 11. Receiving housing; 111. First accommodating cavity; 112. Second accommodating cavity; 113. Positioning stub; 12 Outer housing; 121. First housing; 1211. Insertion hole; 122 Second housing; 123. Gap; 13. Lower cover plate; 131. Mounting holes; 132. Third accommodating cavity; 2. Laser transceiver component; 3. Temperature control component; 31. Semiconductor cooler; 32. Connector; 321. Flexible circuit board; 3211. First horizontal segment; 3212. Bent segment; 3213. Second horizontal segment; 322 Pin; 33. Limiting hole; 4. Conduction circuit board; 41. Ball grid array solder ball; 5. Fastener.

### DETAILED DESCRIPTION

To make the objects, technical solutions and advantages of embodiments of the present invention more apparent, technical solutions in embodiments of the present invention will be clearly and completely described with reference to the figures in embodiments in the present invention. Obviously, the embodiments described here are part of rather than all embodiments of the present disclosure. Based on embodiments in the present invention, all other embodiments obtained by those skilled in the art without making any inventive efforts all fall within the scope of protection of the present invention.

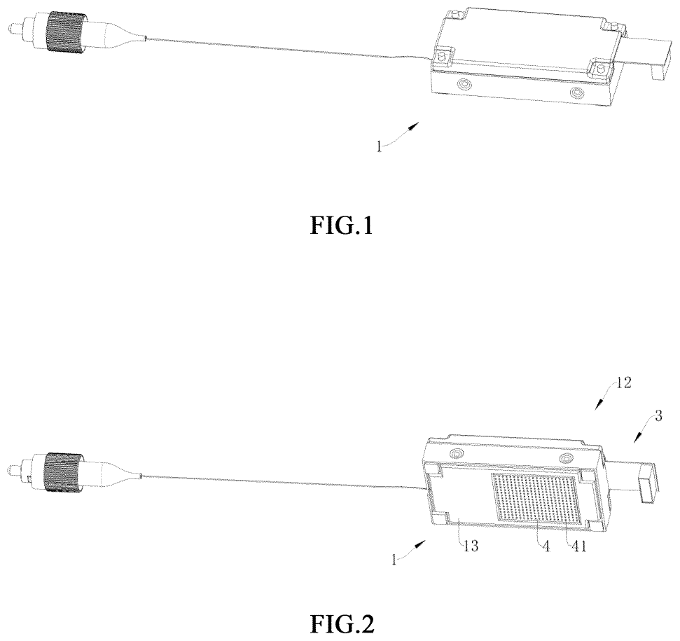

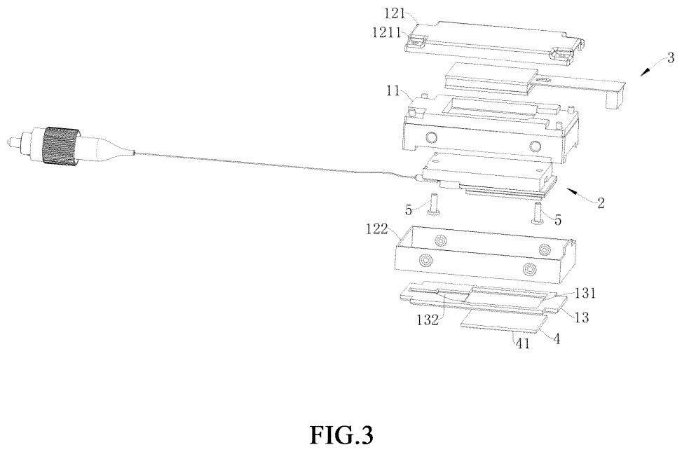

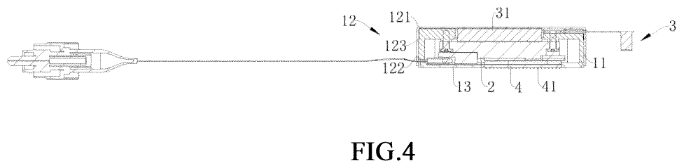

Referring to FIG. 1 through FIG. 4, there is provided an optical package structure for a LIDAR according to a first embodiment of the present invention. The optical package structure for the LIDAR includes a housing 1, a laser transceiver component 2, a temperature control component 3, a conduction circuit board 4 and a plurality of fasteners 5. The laser transceiver component 2 is arranged in the housing 1 and configured to emit a laser beam and to receive for detection. The temperature control component 3 is arranged in the housing 1, connected to the laser transceiver component 2 and configured to adjust the temperature of the laser transceiver component 2. The conduction circuit board 4 is arranged on the housing 1 and electrically connected to the laser transceiver component 2. The optical package structure enables an electrical connection with an external circuit board via the conduction circuit board 4.

The housing 1 includes a receiving housing 11, an outer housing 12 and a lower cover plate 13. The receiving housing 11 is a plastic injection-molded member and arranged to carry the laser transceiver component 2 and the temperature control component 3. The outer housing 12 is arranged to cover the receiving housing 11. The lower cover plate 13 is arranged at a bottom of the receiving housing 11.

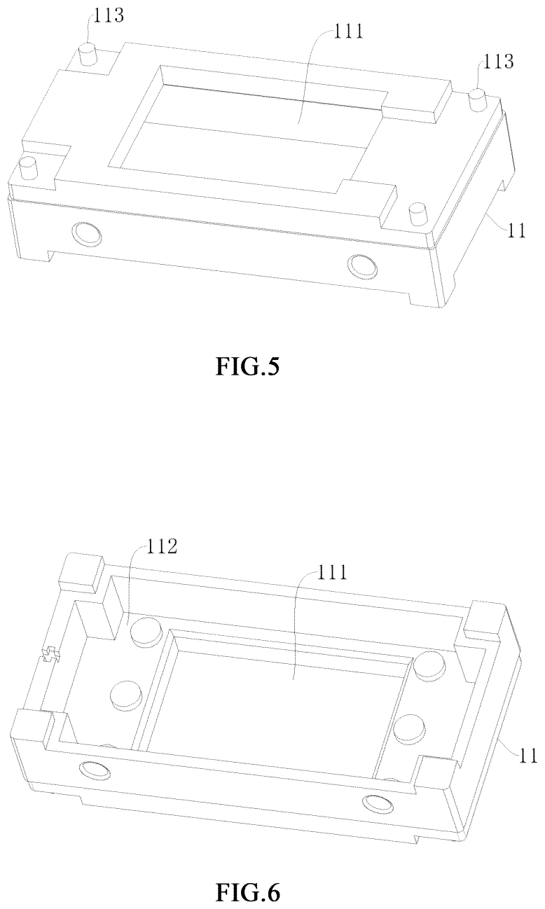

Specifically, referring to FIG. 5 and FIG. 6, a first accommodating cavity 111 is provided on an upper surface of the receiving housing 11, and a second accommodating cavity 112 is provided on a lower surface of the receiving housing 11. The first accommodating cavity 111 is arranged for placing the temperature control component 3. The second accommodating cavity 112 corresponds to the first accommodating cavity 111 and is arranged for carrying the laser transceiver component 2. Specifically, the temperature control component 3 includes a semiconductor cooler 31 and a connector 32. The semiconductor cooler 31 is placed in the first accommodating cavity 111; and the connector 32 is connected to the semiconductor cooler 31. A cold end of the semiconductor cooler 31 is connected to the laser transceiver component 2, and a hot end of the semiconductor cooler 31 is connected to the outer housing 12. In the present embodiment, the first accommodating cavity 111 is communicated with the second accommodating cavity 112, and the cold end of the semiconductor cooler 31 is directly contacted with and connected to the laser transceiver component 2, which is beneficial to improve the efficiency when the temperature control component 3 adjusts the laser transceiver component 2. In the present embodiment, the laser transceiver assembly 2 is mounted within the second accommodated cavity 112 by fasteners 5, and part of electronic devices on the laser transceiver assembly 2 abut against the lower cover plate 13. The fasteners 5 are bolts. In other embodiments, the laser transceiver module 2 may also be adhesively mounted in the second accommodating cavity 112. The mounting manner of the laser transceiver module 2 is not limited thereto.

The outer housing 12 includes a first housing 121 and a second housing 122. The first housing 121 and the second housing 122 are both metal members. The first housing 121 is arranged on an upper surface of the receiving housing 11, and the first housing 121 is connected to the hot end of the semiconductor cooler 31 and has a heat-dissipating function and an electromagnetic shielding function. The second housing 122 is to outside surround the receiving housing 11 and has an electromagnetic shielding function. An insertion hole 1211 is provided at each of four corners of the first housing 121. A positioning stub 113 is provided at each of four corners of the upper surface of the receiving housing 11, and the positioning stubs 113 correspond one-to-one with the insertion holes 1211. Upon assembling, the positioning stubs 113 are inserted into the insertion holes 1211, so that the first housing 121 is quickly assembled on the receiving housing 11 by an operator, thereby simplifying the assembling process and improving the assembling efficiency. Then, the assembling between the first housing 121 and the receiving housing 11 is completed by fastening and connecting the first housing 121 with the receiving housing 11 using a hot pressing process.

A gap 123 is existed between the first housing 121 and the second housing 122. The gap 123 can prevent the first housing 121 from transferring heat to the second housing 122 after absorbing heat from the hot end of the semiconductor cooler 31, and then transferring heat to the receiving housing 11 through the second housing 122, thereby affecting the heat-dissipating effect of the optical package structure. Preferably, a thermal insulation layer is provided in the gap 123 between the first housing 121 and the second housing 122. The thermal insulation layer may be provided as a glue layer, for thermally insulating the first housing 121 from the second housing 122, and further reducing the risk of heat at the first housing 121 being transferred through the second housing 122 to the receiving housing 11.

A mounting hole 131 is provided on the lower cover plate 13, and the conduction circuit board 4 is embedded in the mounting hole 131. Preferably, a third accommodating cavity 132 is further provided on the lower cover plate 13. A shape of the third accommodating cavity 132 matches that of the electronic device arranged on the laser transceiver component 2, which facilitates the assembling of the optical package structure, and makes the structure of the optical package structure more compact.

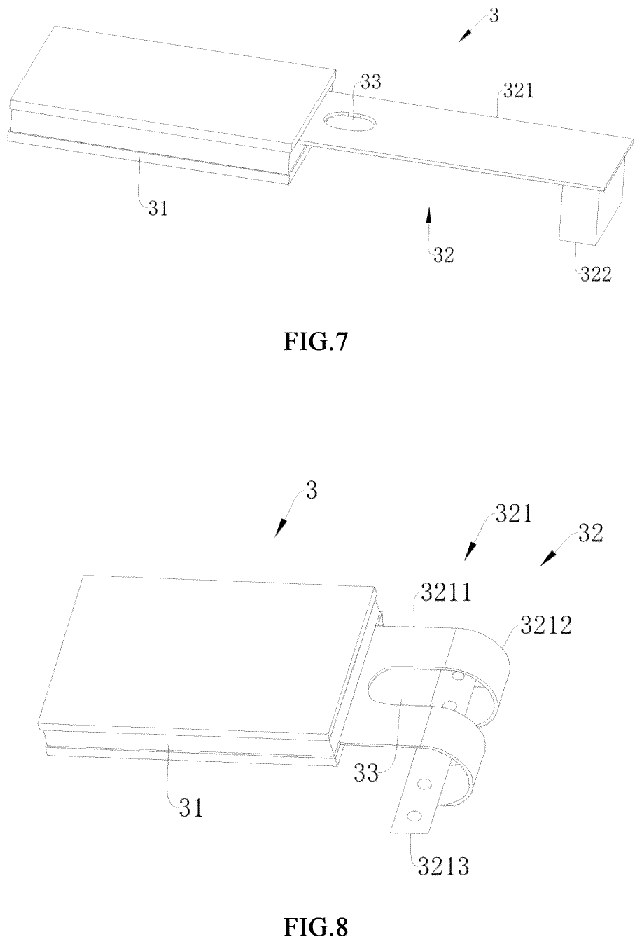

Referring to FIG. 7, the connector 32 in the temperature control component 3 includes a flexible circuit board 321 and a pin 322. The flexible circuit board 321 is connected to the semiconductor cooler 31 and extends to the outside of the housing 1. The pin 322 is arranged on an end of the flexible circuit board 321 away from the housing 1 for electrical connection with an external circuit board. Preferably, an end of the flexible circuit board 321 close to the semiconductor cooler 31 is provided with a limiting hole 33. When the fasteners 5 pass through the laser transceiver component 2 and fixedly mount the laser transceiver component 2 in the second accommodating cavity 112, one of the fasteners 5 also passes through the limiting hole 33, which facilitates improve the structural stability of the optical package structure.

The conduction circuit board 4 is embedded in the mounting hole 131 of the lower cover plate 13, and the conduction circuit board 4 is electrically connected to the laser transceiver component 2. In the present embodiment, the laser transceiver component 2 is electrically connected to the conduction circuit board 4 via gold wire bonding, so as to realize the transmission of the laser and the reception for the detection. A plurality of ball grid array solder balls 41 are provided on a side of the conduction circuit board 4 facing the outside, with good heat dissipation performance, firm pins and good electrical performance. In the present embodiment, the arrangement manner of the ball grid array solder balls 41 is a full array type. In other embodiments, the arrangement manner of the ball grid array solder balls 41 may be a peripheral or staggered type, and is not limited thereto. In the present embodiment, the ball grid array solder balls 41 are tin balls. In other embodiments, the ball grid array solder balls 41 may also be provided as Sn—Ag—Cu solder balls, In—Ag solder balls, Sn—Ag solder balls, etc. and are not limited thereto.

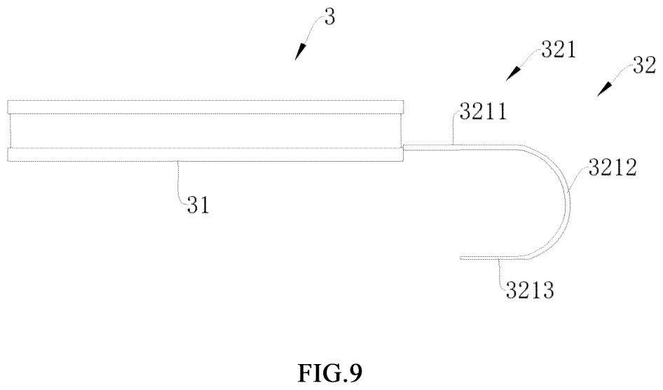

Reference is now made to FIG. 8 and FIG. 9 together, which are schematic diagrams of a temperature control component 3 in an optical package structure for the LIDAR according to a second embodiment of the present invention. In the present embodiment, the temperature control component 3 also includes a semiconductor cooler 31 and a connector 32, and the connector 32 is connected to the semiconductor cooler 31. Differently, the connector 32 includes a flexible circuit board 321 having a U-shaped structure.

The flexible circuit board 321 includes a first horizontal segment 3211, a bent segment 3212 and a second horizontal segment 3213. The first horizontal segment 3211 is connected to the semiconductor cooler 31, the second horizontal segment 3213 is arranged in parallel with the first horizontal segment 3211 and electrically connected to the conduction circuit board 4, and the bent segment 3212 presents a bent structure and connects the first horizontal segment 3211 with the second horizontal segment 3213, so that the first horizontal segment 3211 and the second horizontal segment 3213 can be arranged in parallel and opposite to each other. Preferably, the first horizontal segment 3211, the bent segment 3212, and the second horizontal segment 3213 are in an integrated form. The flexible circuit board 321 with a U-shaped structure occupies a small space in the optical package structure, which facilitates the arrangement of other components; meanwhile, the flexible circuit board 321 can be entirely received in the housing 1, so that the structure of the optical package structure is more compact, which facilitates reducing the volume of the optical package structure and enhancing its compatibility.

An optical component is a core part of the LIDAR module. In the assembling process of the optical component, the precise positioning of the optical component needs to be ensured. Generally, a high-precision AA (Active alignment) machine needs to be used. However, the AA machine is high in price, and complicated in design parameters and processes. Therefore, the iterative update frequency of the optical component structure is generally low, while what has a high update and change frequency in the LIDAR module is a peripheral control circuit. Therefore, the present invention provides an optical package structure for the LIDAR, wherein the laser transceiver component 2 and the temperature control component 3 are packaged in the housing 1, thereby realizing the integration of the parts with lower iterative update frequencies in the LIDAR module into an independent optical package structure; and the optical package structure can be electrically connected to the external circuit board via the conduction circuit board 4. The optical package structure has a compact structure and good versatility. A peripheral control circuit part suitable for different scenarios can be designed by the user according to his or her own demands, and then the optical package structure is electrically connected with the peripheral control circuit part. Thereby, it can meet different users' demands, which facilitates reducing the production and design costs for the user.

The above embodiments are preferred embodiments of the present invention, but embodiments of the present invention are not limited by the above embodiments. Any other variations, modifications, substitutes, combinations and simplifications made without departing from the spirit, essence and principles of the present inventions all should be equivalent replacements and all fall within the scope of protection of the present invention.

I/we claim:

1. An optical package structure for a LIDAR, comprising: a housing (1); a laser transceiver component (2) arranged in the housing (1) and for emitting a laser and receiving for detection; a temperature control component (3) arranged in the housing (1) and connected to the laser transceiver component (2); and a conduction circuit board (4) arranged on the housing (1) and for electrically connecting to an external circuit board, the conduction circuit board (4) is electrically connected to the laser transceiver component (2).

2. The optical package structure for the LIDAR according to claim 1, wherein the housing (1) comprises a receiving housing (11) for supporting the laser transceiver component (2) and the temperature control component (3), an outer housing (12) covering on the receiving housing (11), and a lower cover plate (13) arranged at a bottom of the receiving housing (11), a mounting hole (131) is provided on the lower cover plate (13), the conduction circuit board (4) is embedded within the mounting hole (131).

3. The optical package structure for the LIDAR according to claim 2, wherein an upper surface of the receiving housing (11) is provided with a first accommodating cavity (111) for placing the temperature control component (3); a lower surface of the receiving housing (11) is provided with a second accommodating cavity (112) corresponding to the first accommodating cavity (111) and for supporting the laser transceiver component (2); and
the temperature control component (3) comprises a semiconductor cooler (31) placed in the first accommodating cavity (111) and a connector (32) connected to the semiconductor cooler (31); a cold end of the semiconductor cooler (31) is connected to the laser transceiver component (2); a hot end of the semiconductor cooler (31) is connected to the outer housing (12).

4. The optical package structure for the LIDAR according to claim 3, wherein the first accommodating cavity (111) is communicated with the second accommodating cavity (112); the cold end of the semiconductor cooler (31) is directly in contact with and connected to the laser transceiver component (6).

5. The optical package structure for the LIDAR according to claim 3, wherein the outer housing (12) covering on the receiving housing (11) comprises a first housing (121) arranged on an upper surface of the receiving housing (11) and a second housing (122) covering on an outside of the receiving housing (11), wherein a gap is existed (123) between the first housing (121) and the second housing (122).

6. The optical package structure for the LIDAR according to claim 5, wherein the upper surface of the receiving housing (11) is provided with a plurality of positioning stubs (113); the first housing (121) is provided therein with a plurality of insertion holes (1211) corresponding one-to-one with the positioning stubs (113) and for insertion of the positioning stubs (113).

7. The optical package structure for the LIDAR according to claim 5, wherein a thermal insulation layer for thermally insulating the first housing (121) from the second housing (122) is provided in the gap (123) between the first housing (121) and the second housing (122).

8. The optical package structure for the LIDAR according to claim 3, wherein the connector (32) comprises a flexible circuit board (321) connected to the semiconductor cooler (31) and extending to outside of the housing (1), and a pin (322) arranged at an end of the flexible circuit board (321) away from the housing (1) and electrically connected with the external circuit board.

9. The optical package structure for the LIDAR according to claim 3, wherein the connector (32) comprises a flexible circuit board (321) having a U-shaped structure; the flexible circuit board (321) comprises a first horizontal segment (3211) connected to the semiconductor cooler (31), a second horizontal segment (3213) arranged in parallel with the first horizontal segment (3211) and electrically connected to the conduction circuit board (4), and a bent segment (3212) connecting the first horizontal segment (3211) with the second horizontal segment (3213) and having a bent structure.

10. The optical package structure for the LIDAR according to claim 1, wherein a plurality of ball grid array solder balls (41) are provided on a side of the conduction circuit board (4) facing the outside.
